(19) United States
(12) Patent Application Publication
(10) Pub. No.: US 2005/0221594 A1
(43) Pub. Date: Oct. 6, 2005

(54) ISFET with TiO2 sensing film

(76) Inventors: Jung-Chuan Chou, Yunlin Hsien (TW); Sung-Po Liao, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/865,028

(22) Filed: Jun. 10, 2004

(30) Foreign Application Priority Data
Mar. 31, 2004 (TW) 93108803

(51) Int. Cl. H01L 21/20

(52) U.S. Cl. 438/584

(57) ABSTRACT

A method of manufacturing a titanium dioxide (TiO₂) thin film, used as the sensing film of the ISFET, prepared on the gate oxide by sputtering deposition. It also utilizes current/voltage measuring system to measure the current-voltage curves for the different pH values and temperatures. From the relationship of the current-voltage curves and temperatures, the temperature parameter of the TiO₂ gate pH-ISFET can be calculated. In addition, it also uses a constant voltage/current circuit and a voltage-time recorder to measure the output voltage of the TiO₂ gate pH-ISFET, the drift rates for the different pH values and hysteresis for different pH loops are calculated.

### BACKGROUND OF THE INVENTION

1. Field of the Invention

The present invention relates to a method of manufacturing a TiO₂ sensing film, and in particular to an ISFET with a TiO₂ sensing film, and methods and apparatuses for measuring the temperature parameter, drift, and hysteresis of an ISFET.

2. Description of the Related Art

The Ion Sensitive Field Effect Transistor (ISFET) was presented by Piet Bervgeld in 1970. The ISFET with reference electrode is similar to Metal-Oxide-Semiconductor Field Effect Transistor (MOSFET), except that the ISFET has exposed the gate insulator to measure a selected ion concentration in electrolyte. When the pH-ISFET is immersed in an aqueous solution, a surface potential is induced at the surface of the sensing membrane of the pH-ISFET. However, the surface potential at the sensing membrane will affect the carrier concentration within the inversion layer of the semiconductor, due to the gate dielectric layer being extremely thin. Thus, the current, which flows through the channel, is adjusted. Furthermore, the surface potential is related to the hydrogen ion activity within the aqueous solution. As the pH values change, different surface potentials are induced at the sensing membrane, leading to different channel currents. Thus, the pH-ISFET can be used to detect the pH values of solution.

A number of the patents relating to ISFETs are listed hereinafter.

U.S. Pat. No. 5,350,701 issued to Nicole Jaffrezic-Renault, Chovelon Jean-Marc, Hubert Perrot, Pierre Le Perchec, and Yves Chevalier on Sep. 27, 1994 discloses a process for producing a surface gate comprising a selective membrane for an integrated chemical sensor comprising a field effect transistor, and the integrated chemical sensor thus produced, wherein the surface gate is particularly sensitive to the alkaline-earth species, and more particularly, sensitive to the calcium ion. The process comprises forming grafts on the surface gate, and making the grafts operative utilizing phosphonate-based, ion-sensitive molecules.

U.S. Pat. No. 5,387,328 issued to Byung Ki Sohn, and Daegu on Feb. 7, 1995 discloses a bio-sensor employing an ISFET comprising a source and a drain formed in a substrate, an ion sensitive gate placed between the source and the drain, an ion sensitive film formed on the ion sensing gate, an immobilized enzyme membrane defined on the ion sensitive film and, a Pt electrode formed on the ion sensitive film. The sensor has a Pt electrode capable of sensing all biological substances which generate H₂O₂ in enzyme reaction, and thereby has high sensitivity and rapid reaction time.

U.S. Pat. No. 5,414,284 issued to Ronald D. Baxter, James G. Connery, John D. Fogel, and Spencer V. Silverthorne on May 9, 1995 discloses a method for depositing the ISFET devices and ESD protection circuit on the same substrate. According to one aspect of the invention, an ESD protection circuit, made up of the conventional protective elements, is integrated onto the same silicon chip on which the ISFET is formed, along with an interface that is in contact with the liquid being measured and which does not open up paths for D.C. leakage currents between the ISFET and the liquid. According to a preferred embodiment of the invention, a capacitor structure is used as the interface between the protection circuit and the liquid sample.

U.S. Pat. No. 5,309,085 issued to Byung Ki Soh on May 3, 1994 discloses a measuring circuit with a biosensor utilizing ion sensitive field effect transistors, which is integrated into one chip. The measuring circuit comprises two ion sensitive FET input devices composed of an enzyme FET having an enzyme sensitive membrane on the gate and a reference FET, and a differential amplifier for amplifying the outputs of the enzyme FET and the reference FET.

U.S. Pat. No. 5,061,976 issued to Takeshi Shimomura, Shuichiro Yamaguchi, Takanao Suzuki, and Noboru Oyama on Oct. 29, 1991 discloses a process, wherein a carbon thin membrane is coated on the top of the ISFET. And the surface of the latter is coated with an electrolytic polymerization membrane of 2,6 xylenol. The ISFET obtained exhibits the hydrogen-ion selectivity, little drift, high stability and little response to light. If the surface of the electrolytic polymerization membrane of 2,6-xylenol is coated with another ion-selective membrane or enzyme-active membrane, various ions and the concentration of a biological substrate can be measured.

U.S. Pat. No. 5,833,824 issued to Barry W. Benton on Nov. 10, 1998 discloses an ISFET sensor for sensing ion activity of a solution including a substrate and an ISFET semiconductor die. The front surface of the substrate is exposed to the solution, a back surface opposites to the front surface and aperture extending between the front and back surfaces. The ISFET semiconductor die has an ion-sensitive surface with a gate region. The ion-sensitive surface is mounted to the back surface such that the gate region is exposed to the solution through the aperture.

U.S. Pat. No. 4,691,167 issued to Hendrik H. V. D. Vlekkert, and Nicolaas F. de Rooy on Sep. 1, 1987 discloses an apparatus to determine the activity of an ion in a liquid. The system consists of a measuring circuit, an ISFET, a reference electrode, a temperature sensor, amplifiers, and controller, computing and memory circuits. The sensitivity of the apparatus, as a function of the temperature and/or the variation of the drain-source current, ID, as a function of the temperature are controlled by controlling the VGS so that the sensitivity can be calculated from a formula stored in the memory.

U.S. Pat. No. 5,130,265 issued to Massimo Battilotti, Giuseppina Mazzamurro, Matteo Giongo on Jul. 14, 1992 discloses a process for obtaining a multifunctional ion-selective-membrane sensor. The processes consist of (a) preparation of a siloxanic prepolymer on an ISFET device, (b) preparation of a solution of the siloxanic prepolymer, (c) photochemical treatment in the presence of a photonitiator by means of UV light, (d) chemical washing of the sensor, by an organic solvent, and (e) thermal treatment to complete the reactions of the polymerization.

U.S. Pat. No.4,660,063 issued to Thomas R. Anthony on April 21, 1987 discloses a process using a two-step process involving laser drilling and solid-state diffusion to form the three-dimensional diode arrays in the semiconductor wafers. The holes are first produced in the wafer in the various arrays by laser drilling. Under suitable conditions, the laser drilling causes little or no damage to the wafer. The cylindrical P-N junctions are then formed around the laser-drilled holes by diffusing an impurity into the wafer from the walls of the hole. A variety of distinctly different ISFET devices are produced.

U.S. Pat. No. 4,812,220 issued to Takeaki Lida and Takeshi Kawabe on May 14, 1989 discloses an enzyme sensor for determining a concentration of the glutamate comprising an immobilizing enzyme acting specifically on a substrate and a transducer for converting the quantitative change of a substance or heat which is produced or consumed during an enzyme reaction to an electrical signal, wherein the enzyme is the glutamine synthetase and the transducer is the pH glass electrode or ISFET. The enzyme sensor can be miniaturized and can accurately determine a concentration of the glutamate even when it is low.

As can be seen from the cited patents, a variety of materials were used to act as the sensing membranes of ISFETs, such as, Al₂O₃, Si₃N₄, a-WO₃, a-C:H, and a-Si:H, etc. Additionally, the thin films are deposited by plasma enhanced chemical vapor deposition (PECVD), therefore, the cost of the thin film fabrication is relatively high. For commercial purposes, an easily fabricated, low cost thin film is desirable.

Since TiO₂ pH-ISFETs are semiconductor devices, they are easily influenced by temperature variations. Temperature variations lead measurement deviations. To ensure proper operation, ISFET devices must operate at a constant temperature.

“Hysteresis” is affected by the slow response of the pH-ISFET. There are different output voltages when the pH-ISFET is measured through the pH loop, pHₓ→pH_{y}→pHₓ→pH₂→pHₓ. Hysteresis is defined as the voltage deviation of first and last time at pHₓ.

“Drift” behavior exists during the entire measurement process. When the intrinsic response of the pH-ISFET is complete, the output voltage of the pH-ISFET still varies with time gradually and monotonically. The drift rate is defined as the slope of the output voltage with respect to time.

### SUMMARY OF THE INVENTION

An object of the invention is to provide a low cost and easy method of manufacturing a TiO₂ film as a hydrogen ion sensing film. In the present invention, the manufacture of the film by sputtering has the advantages of low temperature process, dielectric material sputtering capability, low pressure sputtering, uniform film growth over a large area, and applicability to standard semiconductor production procedures.

Another object of the invention is the usage of the current-voltage curve, which can obtain the sensitivities of an ISFET at different temperatures. Furthermore, it can be used to obtain the temperature parameter, i.e. temperature coefficient of the sensitivity (TCS). The temperature parameter can be used to deduce the pH value of the unknown solutions.

Still another object of the invention is to provide a method and apparatus for measuring the drift rate and hysteresis of the TiO₂ gate pH-ISFET enabling use of the reverse compensation method to obtain an accurate output value.

In order to achieve objects of the invention, the method of manufacturing a TiO₂ sensing film of an ISFET comprises the steps of forming a TiO₂ layer on a gate region of the ISFET by sputtering from a titanium target at an RF power of 145 to 160 watts and a pressure of 0.015 to 0.045 torr in the presence of a mixed gasses comprising argon gas and oxygen gas in a mole ratio of 2:1 to 5:1 at a flow rate of 10 to 100 SCCM; and annealing the TiO₂ layer in the presence of oxygen gas and at an annealing temperature of 450 to 550° C.

The ISFET with a TiO₂ sensing film according to the present invention comprises a semiconductor substrate; a gate oxide layer on the semiconductor substrate; a TiO₂ film, formed by the above described method, overlying the gate oxide layer to form TiO₂ layer gate; a source/drain in the semiconductor substrate on a side of the TiO₂ gate; a conductive wire on the source/drain; and a sealing layer overlying the conductive wire, and exposing the TiO₂ film.

The method of measuring the temperature parameters of an ISFET with a TiO₂ sensing film according to the present invention comprises the steps of contacting the TiO₂ sensing film with a buffer solution and attaining a temperature equilibrium; changing the pH value of the buffer solution, measuring and recording the source-drain current and the gate voltage of the ISFET to obtain a curve at a predetermined temperature; selecting a fixed current from the curve to obtain the sensitivity of the ISFET at the predetermined temperature; and changing the temperature of the buffer solution and repeating the previously described steps to obtain the sensitivities of the ISFET at different temperatures.

The apparatus for measuring the temperature of an ISFET with a TiO₂ sensing film according to the present invention comprises an ISFET with a TiO₂ sensing film as described above; a buffer solution contacting the ISFET; a light-isolating container for the buffer solution; a heater for the buffer solution; a heater for heating the buffer solution; a temperature controller connected to the heater; a test fixer connected to the source and drain of the ISFET; and a current/voltage measuring device connected to the test fixer to measure and record the source-drain current and the gate voltage of the ISFET.

The method of measuring the hysteresis of an ISFET with a TiO₂ sensing film according to the present invention comprises the steps of fixing the drain-source current and the drain-source voltage of the ISFET by a constant voltage/current circuit; contacting the TiO₂ sensing film with a buffer solution; recording the gate/source output voltage of the ISFET by a voltage-time recorder; and changing the pH of the buffer solution and repeating the steps of contacting and recording to measure the hysteresis of the ISFET.

The method of measuring the drift rate of an ISFET with a TiO₂ sensing film according to the present invention comprises the steps of contacting the TiO₂ sensing film with a buffer solution; measuring the gate/source output voltage of the ISFET by a constant voltage/current circuit and recording the gate/source output voltage by a voltage-time recorder; after a period of time, recording the gate/source output voltage by the voltage-time recorder; and calculating the change of the gate/source output voltage in a unit of time to obtain the drift rate of the ISFET.

The apparatus of measuring the hysteresis and the drift rate of an ISFET with a TiO₂ sensing film according to the present invention comprises an ISFET with a TiO₂ sensing film as described above; a buffer solution for contacting the TiO₂ sensing film; a light-isolation container for isolating light and carrying the buffer solution and the ISFET; a heater for heating the buffer solution; a temperature controller connected to the heater; a constant current/voltage circuit coupled to the source and drain of the ISFET; a current/voltage measuring device coupled to the constant current/voltage circuit; and a voltage-time recorder coupled to the constant current/voltage circuit.

### BRIEF DESCRIPTION OF THE DRAWINGS

The present invention can be more fully understood by reading the subsequent detailed description and examples with references made to the accompanying drawings, wherein:

FIG. 1 is a schematic cross section of the TiO₂ ISFET of the present invention;

FIG. 2 shows the setup of the current/voltage measurement system of the present invention;

FIG. 3 shows the setup of the constant voltage constant current measuring system of the present invention;

FIG. 4 shows the set up of the constant voltage/current circuit of the present invention;

FIG. 5 shows the drain current-gate voltage curves of the TiO₂ ISFET, operated at 25° C., of the present invention;

FIG. 6 shows the gate voltage versus pH characteristics of the TiO₂ ISFET at 25° C. of the present invention;

FIG. 7 shows the curves of the sensitivity versus the temperature for the TiO₂ ISFET of the present invention;

FIG. 8 shows the drift rates between pH 1 and pH 13 for the TiO₂ ISFET in a preferred embodiment according to the present invention;

FIG. 9 shows the hysteresis at pH loop 7-3-7-11-7 for the different loop time of the present invention; and

FIG. 10 shows the hysteresis at pH loop 5-1-5-9-5 of the present invention.

### DETAILED DESCRIPTION OF THE INVENTION

The method of manufacturing a TiO₂ sensing film of an ISFET according to the present invention forms a TiO₂ layer on a gate region of the ISFET by sputtering from a titanium target for a period of time in a closed reaction chamber under proper conditions of, for example, gasses, pressures, and RF powers. The gasses used may be a mixture of argon gas and oxygen gas in a molar ratio of 2:1 to 5:1, and preferably 3:1 to 4:1. The flow rate may be 10 to 100 SCCM, and preferably 60 to 100 SCCM. The pressure used may be 0.015 to 0.045 torr, and preferably 0.02 to 0.03 torr. The RF power used may be 145 to 160 watts, and preferably 150 to 155 watts. The resulting TiO₂ layer is annealed in the presence of oxygen gas and at an annealing temperature of 450 to 550° C. for a period of time. The obtained TiO₂ film can serve as a good ion-sensing film.

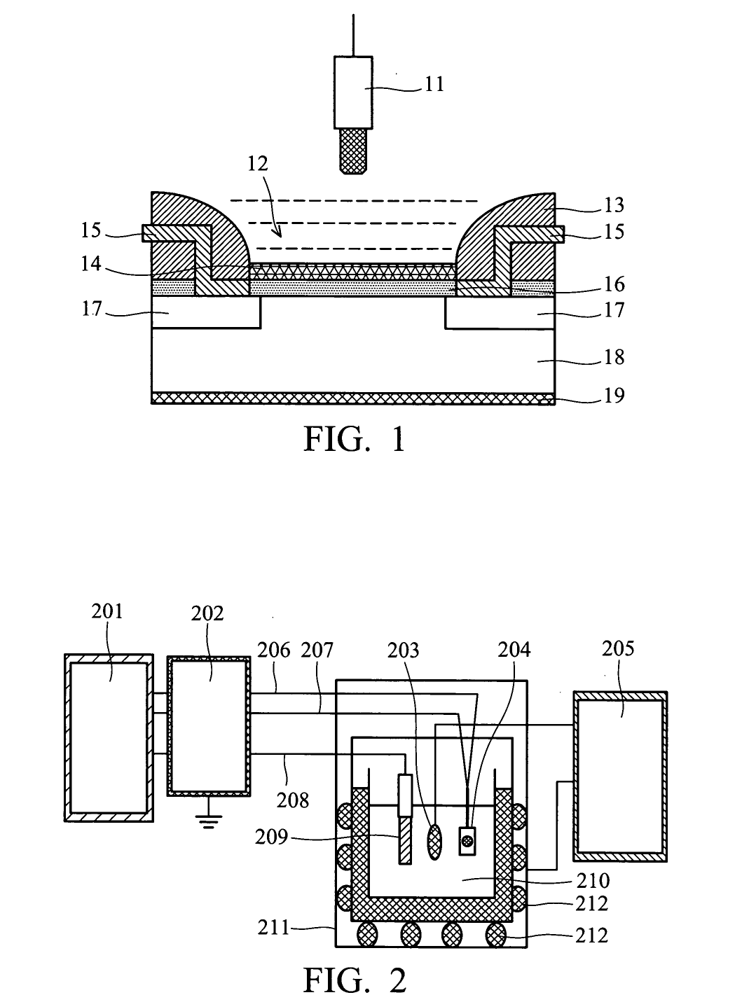

The TiO₂ sensing film according to the present invention can be formed on the gate oxide layer of any type of ISFET by sputtering. The thickness of the film can be controlled in the range of 200 to 300 Å, and preferably 240 to 260 Å, to serve as a sensing film used in ISFET. Please refer to FIG. 1 showing the schematic cross section view of the ISFET with a TiO₂ sensing film (hereinafter referred to as “TiO₂ gate pH-ISFET” or “TiO₂ ISFET”) according to the present invention, in which the structure of the TiO₂ ISFET comprises a semiconductor substrate 18, such as n-type or p-type silicon substrate, optionally on an aluminum plate 19; a gate oxide layer 16, such as silicon dioxide; a source/drain region 17; a conductive wire 15, such as metal wire, for example, aluminum; a TiO₂ film 14 on the gate oxide layer; and a sealing layer 13 (for example, epoxide resin) only exposing the TiO₂ film for detection of the ion concentration in a solution 12. An reference electrode 11 is also shown in FIG. 1.

Please refer to FIG. 2 showing the setup of the current/voltage measurement system of the present invention. The TiO₂ ISFET 204 is immersed into the buffer solution 210 and placed in the dark box 211 for isolation from light. The thermometer 203 can be placed in the buffer solution 210 and connected to the PID temperature controller 205. The heater 212 serves to control the temperature of the buffer solution 210. Finally, the drain/source gate and a reference electrode 209 are connected to the test fixture 202 through conductive wires 206, 207, and 208, and then connected to Keithley 236 current/voltage measure unit 201.

The measurement of temperature parameters of an ISFET is described as follows. The TiO₂ sensing film of the ISFET is contacted with a buffer solution for a period of time, for example, 1.5 minutes, to attain temperature equilibrium. At a predetermined temperature, the pH value of the buffer solution is changed in a range of 1 to 13. A curve of the source/drain current versus gate voltage of the ISFET is obtained through the measurement and recorded by a current/voltage measurement device. The sensitivity of the ISFET at the predetermined temperature can be obtained by selecting a fixed current from the curve of the source/drain current versus gate voltage mentioned above. The sensitivity is the increment of the gate voltage caused by increasing per unit pH at a predetermined temperature. The steps mentioned above are repeated while changing the temperature of the buffer solution, which may be in the range of 5 to 55° C., to obtain the sensitivity at varied temperatures. The temperature parameter (mV/pH ° C.) can be obtained from the curve of temperature-sensitivity, i.e., the slope of the curve. In which, the temperature control is accomplished by controlling a heater with a temperature controller.

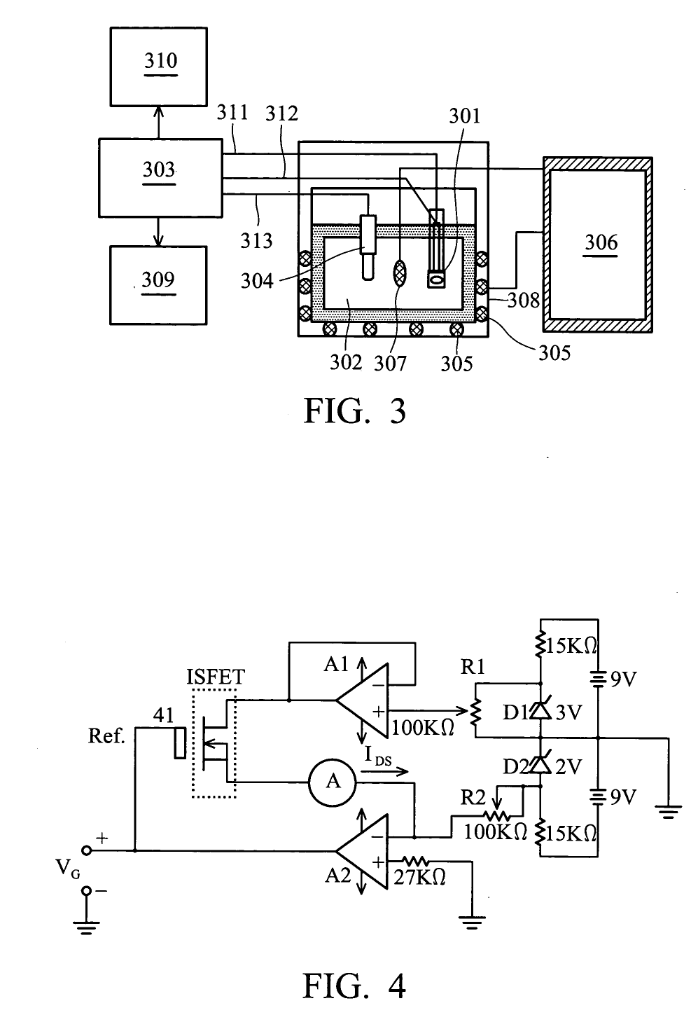

FIG. 3 shows the setup of the constant voltage constant current measuring system in a preferred embodiment according to the present invention. The TiO₂ ISFET 301 and reference electrode 304 are immersed in the buffer solution 302, and placed in the dark box 308. The temperature is controlled by a heater 305 with a temperature controller 306, for example, a PID temperature controller. The temperature can be controlled at 25° C. A thermometer or a thermocouple 307 connected to the temperature controller can be placed in the buffer solution. The drain, source, and gate (a reference electrode 304) regions of the TiO₂ ISFET are connected to the constant voltage/current circuit 303 through the conductive wires 311, 312, and 313. The constant voltage/current circuit may be a negative feedback mode circuit. Finally, the output voltage (V_{G}) of the constant voltage/current circuit 303 is connected to the voltage-time recorder 310 and a current/voltage measuring device 309, for example, a digital multimeter.

The constant voltage/current circuit shown in FIG. 4 utilizes the negative feedback mode to fix the drain-source voltage and current. The response of the device is shown by the gate voltage. The negative feedback is I_{DS}↑→V_{S}↑→V_{G}↓→I_{DS}↓.

The steps for measuring the drift rate of the TiO₂ ISFET are described as follows. The TiO₂ sensing film is contacted with a buffer solution for a period of time, for example, 12 hours, to attain stability. The gate/source output voltage of the ISFET is measured by a constant voltage/current circuit and recorded by a voltage-time recorder. After a period of time, for example, 5 hours, the gate/source output voltage is recorded by the voltage-time recorder. The change of the gate/source output voltage over a unit of time is calculated to obtain the drift rate of the TiO₂ ISFET.

The pH of the buffer solution can be changed to be in the range of 1 to 13 for obtaining the drift rate of the TiO₂ ISFET in the buffer solution at varied pH values. The drain-source current can be fixed at 10 to 300 μA, and preferably 20 to 80 μA. The drain-source voltage can be fixed at 0.1 to 0.2V.

The steps for measuring the hysteresis are described as follows. First, the drain-source current and the drain-source voltage of the TiO₂ ISFET are fixed in a constant voltage/current circuit, wherein the drain-source current can be fixed at 10 to 300 μA, and preferably 20 to 80 μA. The drain-source voltage can be fixed at 0.1 to 0.4V, and preferably 0.1 to 0.2V. Next, the TiO₂ sensing film is contacted with a buffer solution or placed in a standard solution for stability. The gate/source output voltage of the ISFET is recorded by a voltage-time recorder. The hysteresis is the change in the gate/source output voltage from the first measuring point to the final measuring point at the same pH value. Thus, the steps described above are repeated in the buffer solution with different pH values to measure the hysteresis of the TiO₂ ISFET. The pH of the buffer solution can be changed in the order of 7-3-7-11-7, pH step=1, a general order for an acidic or basic solution. Different pH loops result in different hysteresis. For each pH value, the TiO₂ ISFET can be dipped into the buffer solution for 1, 2, 4, and 8 minutes, respectively.

### EXAMPLES

### Example 1

### The Manufacture of the TiO₂ Sensing Film

In a reaction chamber of a vacuum sputter at a pressure less than 10⁻⁶ torr, a mixed gas of Ar/O₂ (80/20 in molar ratio) at a flow rate of 100 SCCM was allowed to enter the chamber and then the pressure was controlled at 0.03 torr. The RF power was set at 150 W, and the titanium target (purity of 99.99%) with a diameter of 2 inches and a thickness of 6 mm was used, to perform the deposition of TiO₂ on the gate region on a semiconductor substrate for 2 hours. The resulting TiO₂ film was annealed for 1 hour at 500° C. in the presence of oxygen, to obtain a TiO₂ sensing film with a thickness of 256 Å.

The TiO₂ ISFET was manufactured on the p-type Si (100) wafer (8˜12 Ω.cm). The channel length and channel width between the source and drain were 50 μm and 1000 μm, respectively. The thickness of the gate oxide layer (SiO₂) was 1000 Å.

### Example 2

### The Measurement of Drift Rate and Hysteresis

The drift rate and hysteresis of TiO₂ ISFET as obtained from Example 1 were measured using the apparatus as shown in FIG. 3. The constant voltage/current circuit as shown in FIG. 4 was used. In which, an operational amplifier (OP) A1 was connected as a voltage follower, and an operational amplifier A2 was used to adjust the voltage of the reference electrode in a negative feedback mode to maintain the constant voltage and constant current between the source and drain. The source/drain voltage was regulated by a variable resistance R1, and the source/drain current was regulated by a variable resistance R2. The source/drain voltage and current were measured by two digital multimeters. The gate voltage, V_{G}, is the output voltage of the TiO₂ ISFET.

The Measurement of the Drift Rate:

First, IDS was fixed at 50 μA and V_{DS} was fixed at 0.2 V by the constant voltage/current circuit. Next, the TiO₂ ISFET was immersed in a buffer solution at pH 1 for 12 hours. Subsequently, the output voltage, V_{G}, of the ISFET was measured by the constant voltage/current circuit and recorded by a voltage-time recorder. The device was placed in the buffer solution at pH values of 2 to 13 and measured for the V_{G}, respectively. The drift rate was obtained from the slope of the output voltage-time curve, where the time was more than 5 hours.

The Measurement of the Hysteresis:

First, the TiO₂ ISFET was measured at pH loop 7-3-7-11-7, pH step=1. For each pH value, the TiO₂ ISFET was dipped in the buffer solution for 1, 2, 4, and 8 minutes, respectively, i.e. loop time were 17, 34, 68, and 136 minutes, respectively.

In addition, the hysteresis of the TiO₂ ISFET was also measured at pH loop 5-1-5-9-5, pH step=1, and for each pH value, the TiO₂ ISFET was dipped in the buffer solution for 1 minute.

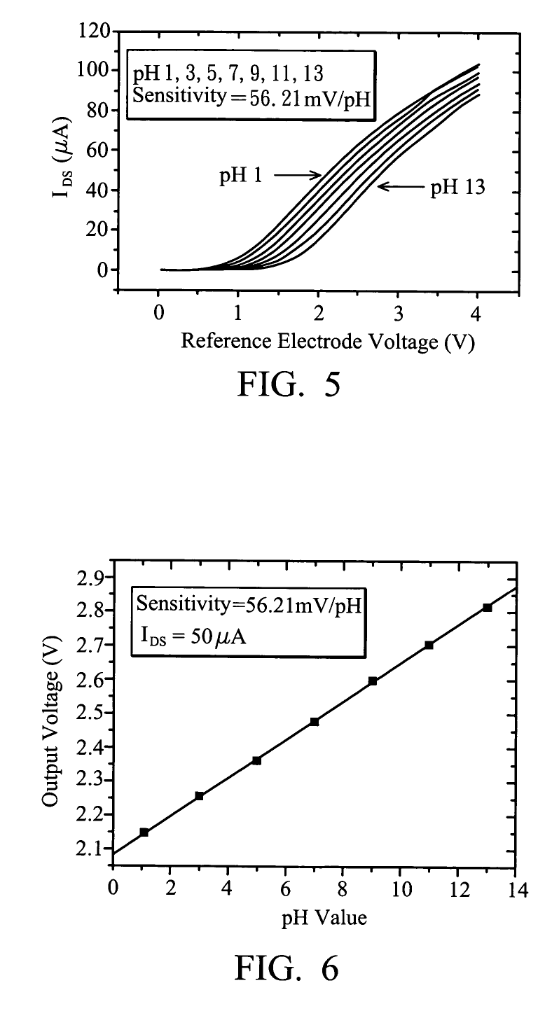

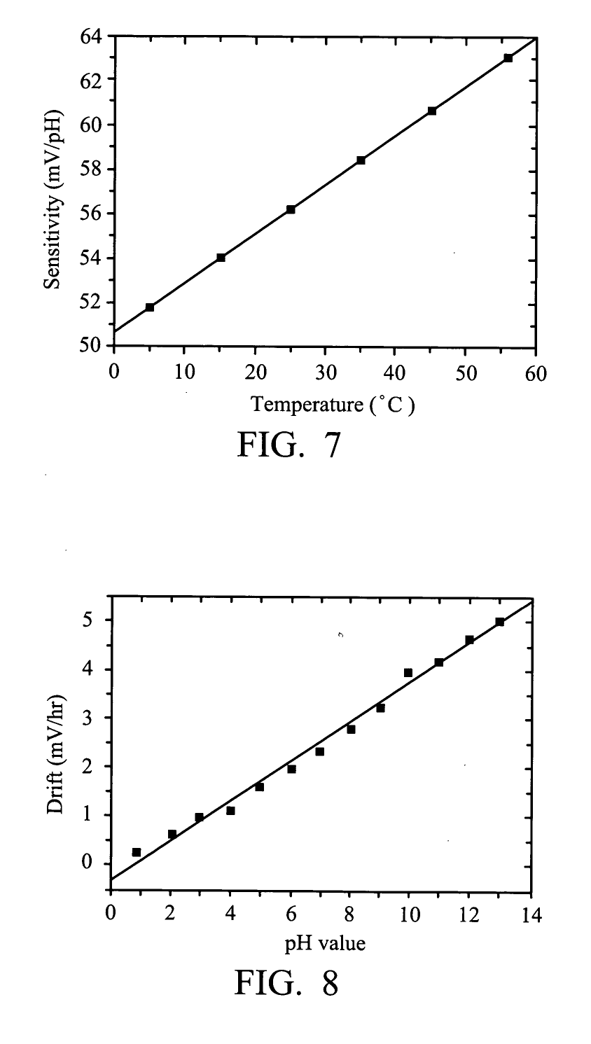

FIG. 5 and FIG. 6 show the pH sensing properties of the TiO₂ ISFET according to the present invention. As shown in the figures, the TiO₂ sensing film of the present invention is suitable for the detection of pH values. FIG. 7 to FIG. 10 show the measurement results of the temperature parameters, drift rates, and hysteresis of the TiO₂ ISFET according to the present invention.

Please refer to FIG. 5 showing the drain current-gate voltage curves of the TiO₂ ISFET according to the present invention, which was operated at 25° C. From FIG. 5, it can be found that the gate voltage increases with increased pH value.

Please refer to FIG. 6 showing the gate voltage versus pH characteristics of the TiO₂ gate pH-ISFET at 25° C. The slope is the sensitivity of the TiO₂ ISFET device, which is about 56.21 mV/pH.

Please refer to FIG. 7 showing the curves of the sensitivity versus the temperature for the ISFET with a TiO₂ sensing film of a preferred embodiment according to the present invention. According to the figures, it can be concluded that the sensitivity increases with increased temperature. The slope of the segment of the curve between 5 to 55° C. is about 0.223 mV/pH ° C.

Table 1 shows sensitivities of the TiO₂ ISFET according to the present invention for the different temperatures of from 5 to 55° C. The sensitivity ranges from 52.81 to 63.01 mV/pH, being 56.21 mv/pH at 25° C.

TABLE 1

Temperature (° C.)

| | 5 | 15 | 25 | 35 | 45 | 55 |
|---|---|---|---|---|---|---|
| Sensitivity | 51.81 | 54.01 | 56.21 | 58.41 | 60.71 | 63.01 |
| (mV/pH) | | | | | | |

Please refer to FIG. 8 showing the drift rates for the TiO₂ gate pH-ISFET for pH 1 to pH 13, measured by the method according to the present invention. It can be found that the drift rate is pH dependent. The drift rate increases with increased pH value.

Table 2 shows the drift rate of the TiO₂ ISFET for pH 1 to pH 13.

TABLE 2

| pH | Drift rate (mV/h) |
|---|---|
| 1 | 0.11 |
| 2 | 0.52 |
| 3 | 0.95 |
| 4 | 1.11 |
| 5 | 1.57 |
| 6 | 1.96 |
| 7 | 2.32 |
| 8 | 2.77 |
| 9 | 3.24 |
| 10 | 3.89 |
| 11 | 4.16 |
| 12 | 4.63 |
| 13 | 5.01 |

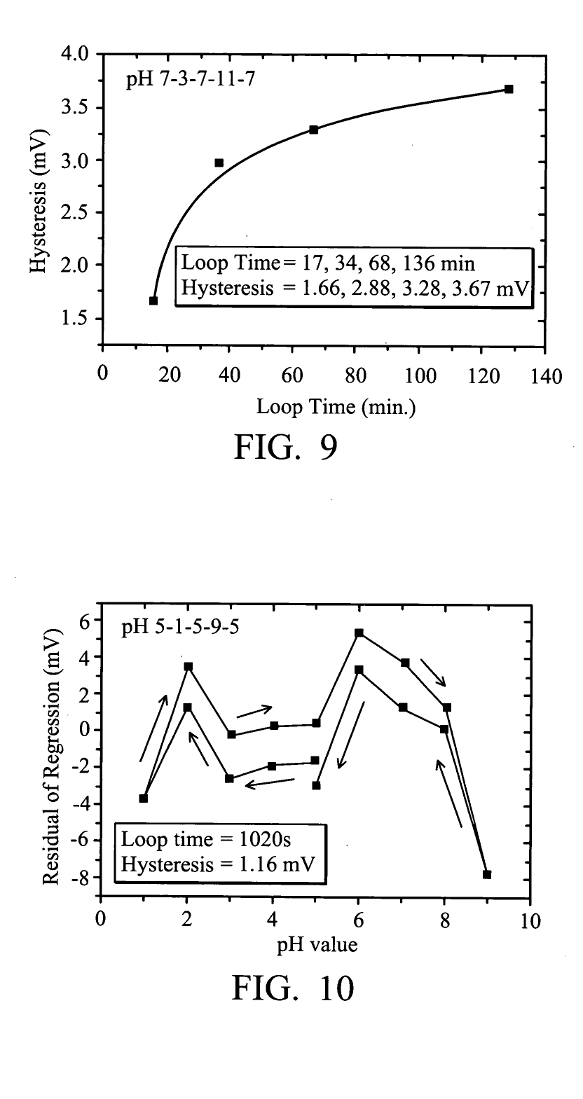

Please refer to FIG. 9 showing the hysteresis at pH loop 7-3-7-11-7 for loop time=17, 34, 68, and 136 minutes. As known from FIG. 9, the hysteresis increases with increased loop time. The hysteresis values for pH loop=pH 7-3-7-11-7 are shown in Table 3.

TABLE 3

| Loop time | Hysteresis |
|---|---|
| (minutes) | (mV) |
| 17 | 1.66 |
| 34 | 2.88 |
| 68 | 3.28 |
| 136 | 3.67 |

Please Refer to FIG. 10 showing the hysteresis at pH loop 5-1-5-9-5 of the TiO₂ ISFET measured by the method of the present invention.

In view of the above description, the advantages of the invention include:

The invention presents a method wherein the titanium dioxide film is prepared to serve as the sensing film for the pH-ISFET by sputtering. The sensitivities of the obtained TiO₂ gate pH-ISFET are good, and the method conforms to standard semiconductor processes. Additionally, there is no research regarding sputtering as means of forming a sensing film for the pH-ISFET. Furthermore, the cost of the TiO₂ thin film deposition is relatively inexpensive.

With the method and apparatus of the present invention, the temperature parameters, drift rate, and hysteresis of the TiO₂ gate pH-ISFET device can be measured precisely.

The method and apparatus of the present invention can also be applied to measure the temperature parameters, drift rate, and hysteresis of other types of the ISFET devices.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method of manufacturing a TiO₂ sensing film of an ISFET, comprising the steps of:
forming a TiO₂ layer on a gate region of the ISFET by sputtering from a titanium target at an RF power of 145 to 160 watts and a pressure of 0.015 to 0.045 torr in the presence of mixed gasses comprising argon gas and oxygen gas in a mole ratio of 2:1 to 5:1 at a flow rate of 10 to 100 SCCM; and
annealing the TiO₂ layer in the presence of oxygen gas and at an annealing temperature of 450 to 550° C.

2. The method as claimed in claim 1, wherein the molar ratio of the argon gas to the oxygen gas is 80:20.

3. The method as claimed in claim 1, wherein the flow rate is 100 SCCM.

4. The method as claimed in claim 1, wherein the pressure is 0.03 torr.

5. The method as claimed in claim 1, wherein the annealing temperature is 500° C.

6. The method as claimed in claim 1, wherein the RF power is 150 W.

7. An ISFET with a TiO₂ sensing film, comprising:
a semiconductor substrate;
a gate oxide layer on the semiconductor substrate;
a TiO₂ film, made from the method as claimed in claim 1, overlying the gate oxide layer to form the TiO₂ layer gate;
a source/drain in the semiconductor substrate on a side of the TiO₂ gate;
a conductive wire on the source/drain; and
a sealing layer overlying the conductive wire, and exposing the TiO₂ film.

8. The ISFET as claimed in claim 7, wherein the length of the channel, the width of the channel, and the width/length ratio of the channel of the ISFET are about 1000 μm, about 50 μm, and about 20, respectively.

9. The ISFET as claimed in claim 7, wherein the semiconductor substrate is P-type.

10. The ISFET as claimed in claim 7, wherein the resistivity of the semiconductor substrate ranges from 8 to 12 Ω.cm.

11. The ISFET as claimed in claim 7, wherein the lattice parameter of the semiconductor is (1,0,0).

12. The ISFET as claimed in claim 7, wherein the thickness of the gate oxide is about 1000 Å.

13. The ISFET as claimed in claim 7, wherein the conductive wire comprises Al.

14. The ISFET as claimed in claim 7, wherein the sealing layer comprises epoxide resin.

15. The ISFET as claimed in claim 7, wherein the source/drain is N-type.

16. A method of measuring the temperature parameters of an ISFET with a TiO₂ sensing film, comprising the steps of:
(b1) contacting the TiO₂ sensing film with a buffer solution and attaining a temperature equilibrium;
(b2) changing the pH value of the buffer solution, measuring and recording the source/drain current and the gate voltage of the ISFET to obtain a curve at a predetermined temperature;
(b3) selecting a fixed current from the curve to obtain the sensitivity of the ISFET at the predetermined temperature; and
(b4) changing the temperature of the buffer solution and repeating the steps of (b1) to (b3) to obtain the sensitivities of the ISFET at different temperatures.

17. The method as claimed in claim 16, wherein the sensitivity is the increment of the gate voltage caused by increasing per unit pH at the predetermined temperature.

18. The method as claimed in claim 17, wherein the predetermined temperature is fixed by a temperature controller and a heater.

19. The method as claimed in claim 1, wherein the predetermined temperature is between 5° C. and 55° C.

20. The method as claimed in claim 1, wherein the pH of the buffer solution is between 1 and 13.

21. An apparatus for measuring the temperature of an ISFET with a TiO₂ sensing film, comprising:
an ISFET with a TiO₂ sensing film as claimed in claim 7;
a buffer solution contacting the ISFET;
a light-isolating container for the buffer solution;
a heater for heating the buffer solution;
a temperature controller connected to the heater;
a test fixer connected to the source and drain of the ISFET; and
a current/voltage measuring device connected to the test fixer to measure and record the source-drain current and the gate voltage of the ISFET.

22. The ISFET as claimed in claim 21, further comprising a reference electrode with one end contacting the buffer solution and the other end connected to the test fixer.

23. The ISFET as claimed in claim 21, wherein the temperature controller is a PID temperature controller.

24. A method of measuring the hysteresis of an ISFET with a TiO₂ sensing film, comprising the steps of:
(c1) fixing the drain/source current and the drain/source voltage of the ISFET by a constant voltage/current circuit;
(c2) contacting the TiO₂ sensing film with a buffer solution;
(c3) recording the gate/source output voltage of the ISFET by a voltage-time recorder; and
(c4) changing the pH of the buffer solution and repeating the steps of (c2) to (c3) to measure the hysteresis of the ISFET.

25. The method as claimed in claim 24, wherein the hysteresis is the change in the gate/source output voltage from the first measuring point to the final measuring point.

26. The method as claimed in claim 24, wherein the source-drain current is fixed at 50 μA, and the drain-source voltage is fixed at 0.2V.

27. The method as claimed in claim 24, further comprising immersing the ISFET in a standard solution to maintain stability prior to the step (c2).

28. The method as claimed in claim 24, wherein the pH is changed in the order of 7, 3, 7, 11, and 7.

29. The method as claimed in claim 24, wherein each pH value of the buffer solution is fixed for one minute.

30. A method of measuring the drift rate of an ISFET with a TiO₂ sensing film, comprising the steps of:
(d1) contacting the TiO₂ sensing film with a buffer solution;
(d2) measuring the gate/source output voltage of the ISFET by a constant voltage/current circuit and recording the gate/source output voltage by a voltage-time recorder;
(d3) after a period of time, recording the gate/source output voltage by the voltage-time recorder; and
(d4) calculating the change of the gate/source output voltage in a unit of time to obtain the drift rate of the ISFET.

31. The method as claimed in claim 30, further comprising a step of changing the pH of the buffer solution to measure the drift rates of the ISFET at different pH values.

32. The method as claimed in claim 30, wherein the gate/source current is fixed at 50 μA, and the drain-source voltage is fixed at 0.2V.

33. The method as claimed in claim 30, wherein in the step of (d1), the TiO₂ sensing film is contacted with the buffer solution for 12 hours to maintain stability.

34. The method as claimed in claim 30, wherein the period of time in the step (d3) is 5 hours.

35. The method as claimed in claim 30, wherein the pH value of the buffer solution is between 1 and 13.

36. An apparatus of measuring the hysteresis and the drift rate of an ISFET with a TiO₂ sensing film, comprising:
an ISFET with a TiO₂ sensing film as claimed in claim 7;
a buffer solution for contacting the TiO₂ sensing film;
a light-isolation container for isolating light and carrying the buffer solution and the ISFET;
a heater for heating the buffer solution;
a temperature controller connected to the heater;
a constant current/voltage circuit coupled to the source and drain of the ISFET;
a current/voltage measuring device coupled to the constant current/voltage circuit; and
a voltage-time recorder coupled to the constant current/voltage circuit.

37. The apparatus as claimed in claim 36, further comprising a reference electrode with one end contacting the buffer solution and the other end connected to the constant voltage/current circuit.

38. The apparatus as claimed in claim 36, further comprising a thermometer with one end contacting the buffer solution and the other end coupled to a temperature controller.

39. The apparatus as claimed in claim 38, wherein the temperature of the buffer solution is fixed at 25° C. by the temperature controller.

40. The apparatus as claimed in claim 36, wherein the constant voltage/current circuit is a negative feedback circuit.

41. The apparatus as claimed in claim 36, wherein the current/voltage measuring device is a digital multimeter.
